(19) United States
(12) Patent Application Publication
(10) Pub. No.: US 2013/0162259 A1
(43) Pub. Date: Jun. 27, 2013

(54) REFERENCE REUSE IN HIGH VOLTAGE STACK MONITORING

(71) Applicant: John WYNNE, Limerick City (IE)

(72) Inventor: John WYNNE, Limerick City (IE)

(73) Assignee: ANALOG DEVICES, INC., Norwood, MA (US)

(21) Appl. No.: 13/333,889

(22) Filed: Dec. 21, 2011

(51) Int. Cl. G01R 31/36; G01N 27/416; G01R 35/00

(52) U.S. Cl. 324/433; 324/426; 702/63

(57) ABSTRACT

A system and method for developing highly accurate measurements by calibrating monitoring units with the known accurate measurements of an adjacent monitoring unit, thereby limiting the number of accurate references needed to accurately read a component stack. In a voltage stack having multiple packs with multiple cells per pack, a voltage reference with a known accuracy may be associated with a single pack. A monitoring unit may measure the overall voltage of the first pack and the combined voltage potential of the first pack and an adjacent pack. A second monitoring unit, having a different reference voltage, may then measure the overall voltage of the second pack. The two measurements of the second pack voltage may be compared and a correction factor may be calculated that may be used to correct subsequent measurements from the second pack.

### BACKGROUND

Aspects of the present invention relate generally to the field of electronic signal processing and more specifically to improving measurement accuracy in systems with limited accurate references.

In a typical high voltage stack, groups or packs of low voltage cells are connected in series to generate an overall high voltage. For example, a high-voltage battery stack may be composed of multiple battery cells arranged in series. Each cell typically only has a potential difference of a few volts (say 2 to 5 volts) developed across it. Then, a large number of cells may be arranged in series such that, for example, the total potential difference developed across the stack is in the order of several hundred volts.

Although the cells are similar, they are not identical, so repeated charging and discharging cycles may develop unequal voltages across individual cells within the stack. Ideally, the voltage across each individual cell, or at least across a small group of cells, would be monitored such that the cells could be temporarily removed from a charging process if their terminal voltage gets too high or if the cell temperature becomes unduly elevated. It is also possible to preferentially discharge cells to reduce their voltage.

Therefore, each cell or pack of cells may be monitored by a cell monitor having an analog to digital converter (ADC). Each ADC may have a reference voltage to facilitate the conversion, which may be a source of measurement errors and variations. For example, temperature can cause reference voltages in a monitor to change. Such voltage reading variations may lead to a significant statistical offset in the cell measurements.

In some applications, the values calculated by the cell monitors need to be highly accurate and measurement errors limited. Correspondingly each associated reference voltage must also be highly accurate. However, implementation of highly accurate reference voltages associated with each monitor for each monitored cell is cost prohibitive.

Therefore, there is a need in the art for an efficient and highly accurate monitoring system for cells implemented in series to reduce cell monitor measurement errors.

### BRIEF DESCRIPTION OF THE DRAWINGS

The foregoing and other aspects of various embodiments of the present invention will be apparent through examination of the following detailed description thereof in conjunction with the accompanying drawing figures in which similar reference numbers are used to indicate functionally similar elements.

FIG. 1 is a simplified block diagram of an exemplary voltage stack arranged according to an embodiment of the present invention.

FIG. 2 is a simplified block diagram of an exemplary monitoring system according to an embodiment of the invention.

FIG. 3 is a simplified block diagram of an exemplary voltage stack arranged according to an embodiment of the present invention.

FIG. 4 illustrates an exemplary method for calibrating a monitoring system according to an embodiment of the present invention.

FIG. 5 is a simplified block diagram of an exemplary group of voltage modules arranged according to an embodiment of the present invention.

### DETAILED DESCRIPTION

In many signal measurement systems today there can be many individual signals or channels which need to be measured or monitored by conversion electronics. Groups of signals may be captured for conversion by ADC modules. In a voltage stack having multiple packs with multiple cells per pack, a very accurate voltage reference may be associated with a single pack, usually the lowest in a string of packs, containing an ADC. Using a pair of resistive dividers, the ADC may measure the overall voltage of the first pack and the combined voltage potential of the first pack and an adjacent pack. The overall voltage of the second pack is subsequently computed. The adjacent pack may have its own pack voltage and a common mode voltage equal to the first pack voltage. A second ADC module, having a less accurate reference voltage, may then measure the overall voltage of the second pack. The two separate measurements of the second pack voltage may be compared and a correction factor may be calculated that may be used to adjust subsequent measurements from the second pack. The correction factor may represent in part a gain or offset error induced during the conversion process by the tolerance margin of the reference voltage in the second pack.

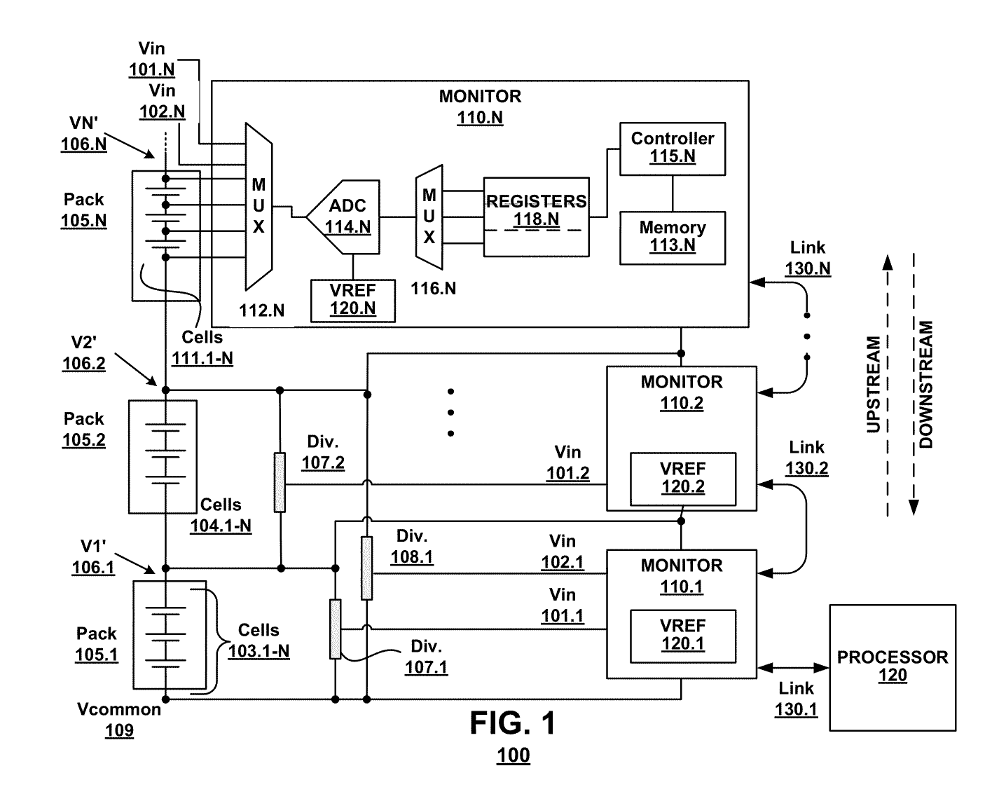

FIG. 1 is a simplified block diagram of an exemplary monitoring system 100 arranged according to an embodiment of the present invention. As shown in FIG. 1, the monitoring system 100 may include multiple voltage packs 105. Each pack 105 may include one or more voltage cells 103, 104, 111. Each cell may have a small potential difference of a few volts developed across it. Then, multiple cells arranged in series may create a larger potential difference developed across each pack such that the total potential difference developed across the pack 105 is higher than each cell 103, 104, 111. When multiple packs 105.1-105.N are arranged in series to form a stack, the total potential difference of the stack may be significantly higher than any one cell 103, 104, 111 or pack 105.

For example, if a pack 105.1 is composed of 12 cells 103.1-103.12, each cell 103 nominally developing 4V, then the pack 105.1 may develop a potential difference of 48V across the pack and this voltage V1′ 106.1-Vcommon 109 may equal 48V. Then if two packs 105.1, 105.2 are arranged in series to form a stack, the total potential difference developed across the two packs may be equivalent to 96V at V2′ 106.2 with respect to Vcommon 109. As will be evident, if additional packs are arranged in series, the potential difference for a stack may be very high, on the order of hundreds of volts.

The monitoring system 100 may include one or more monitoring units 110.1-110.N and a processor 120. The processor 120 may be coupled to the monitoring units 110.1-110.N via communication links 130.1-130.N, which typically are serial bus communication links. As shown with respect to monitoring unit 110.N, the monitoring units 110.1-110.N may have inputs coupled to respective cells of a battery system. A monitoring unit 110 may include: a first multiplexer (“MUX”) 112.N having inputs coupled to the battery cells 111.1-N; an analog-to-digital converter (“ADC”) 114.N coupled to an output of the respective MUX 112.N; a second MUX 116.N coupled to an output of the ADC 114.N; and a register file 118.N for storage of digital data output by the ADC 114.N.

In implementation, each monitoring unit may be configured to accept inputs from a predetermined number of cells. For example, the configuration illustrated in FIG. 1 shows monitoring unit 110.N with six inputs which provide capability to monitor three differential battery cells and two other voltages with respect to V2′ 106.2; these two other voltages are Vin 101.N which is the pack voltage directly monitored by monitor unit 110.N, and the second voltage is Vin 102.N which is the combined voltage of itself and the pack above it in a string. In this regard, the monitoring units 110.1-110.N are considered to be multi-channel devices. The register file 118.N may have a number of registers that correspond to the number of channels supported by the monitoring unit 110.N. In many implementations of such a system it may also necessary to measure the temperature of each cell, these measurement channels are not shown in FIG. 1. Other implementations may be provided having a different number of channels than illustrated here.

As noted, the processor 120 may be connected to the monitoring units 110.1-110.N by a variety of communication links, which may operate in a “daisy chain” fashion. In the configuration illustrated in FIG. 1, the communication links may be provisioned as a plurality of serial busses 130.1-130.N. The processor 120 is directly connected to a first monitoring unit 110.1 by a first serial link 130.1. The first monitoring unit 110.1 is connected to a second monitoring unit 110.2 via a second serial link 130.2. Monitoring units at intermediate positions within the daisy chain are connected to a downstream monitoring unit by one serial link and to an upstream monitoring unit by a second serial link. The final monitoring unit 110.N is connected to a prior monitoring unit by a final serial link 130.N.

Alternatively, in an embodiment, the monitoring units 110 may not be linked with a daisy chain but rather monitor 110.2 may be connected to processor 120 via an electrical isolation barrier. Similarly monitor 113.N may be connected to processor 120 via another electrically isolated barrier (not shown).

The serial links may define a communication flow in two directions: an upstream directions and a downstream direction. In the upstream direction, processor commands are communicated from the processor 120 to the first monitoring unit 110.1 and relayed among the monitoring units until they reach the last monitoring unit in the chain 110.N. In a downstream direction, any monitoring unit (say, monitoring unit 110.2) may transmit a message and convey it to an adjacent monitoring unit (monitoring unit 110.1) in the direction of the processor. Intermediate monitoring units would relay the message down the daisy chain until a final monitoring unit (monitoring unit 110.1) delivers the message to the processor. In this regard, the monitoring units 110-110.N may include transceiver circuitry to manage communication flow across the communication links 130.1-130.N.

During a conversion operation, the first MUX 112.N may activate a pair of inputs associated with a cell (a “channel”) being tested. Voltages from the inputs may then be routed to the ADC 114.N. The ADC 114.N, using a reference voltage VREF 120.N, may sample a voltage across the cell and may convert it to a digital value representing the sampled voltage. The digital value has a predetermined bit width, for example, 14 bits. The ADC 114.N may output the digital value to a register associated with the channel being sampled. The monitoring unit 110.N may sample and digitize voltages of each of the channels in turn (controlled via an internal state machine) and store digital values for each channel in the register file 118.N. For clarity, these implementations are not shown, but each monitoring unit 110.1-110.N may operate in this manner.

If the reference voltage VREF 120 is highly accurate, the measurement and conversion of the input signal Vin 101 may be highly accurate. A reference voltage may be considered accurate if it has a tight tolerance or relatively small margin of error. However, implementing a highly accurate ADC and voltage reference for each monitoring unit is not cost effective, therefore, a single highly accurate monitoring unit 110 may be configured to calibrate neighboring monitoring units. Depending on the accuracy and tolerance of the reference voltage, the conversion process may result in offset of gain errors in the converted signal, accordingly, the monitoring unit may be implemented with a controller 115 that receives an input representing the total pack voltage Vin 101 and an input that represents the total pack voltage of an adjacent pack Vin 102. Then the inputs may be converted and the measurement of the voltage of the adjacent pack may be passed to that pack for use in calculating a correction factor.

Therefore, the potential difference developed across each stack may additionally be measured by the monitoring unit 110. However, the voltage of the pack 105 may be too large for the monitoring unit to measure, therefore the voltage may be divided by a voltage divider 107 to create a voltage input that may be effectively measured by the monitoring unit 110. Monitoring unit 110 may be configured to receive a voltage input Vin 101 from a voltage divider 107, for example a resistive divider, representing a fraction of the voltage developed across the pack 105. As shown, an exemplary resistive divider may divide down the total voltage produced by the pack to be measured by the monitoring unit 110. The output Vin 101 of the resistive divider 107 may be calculated according to Equation 1.

$${V}_{in} = \frac{{R}_{1}}{{R}_{1} + {R}_{2}} \times {V}_{1} \qquad EQ . 1$$

For example, in an exemplary implementation, if the voltage created across the pack 105.1 is 48V, and if the voltage divider includes two resistors, R1=1R and R2=19R, then in accordance with Equation 1, the developed signal is divided by 20 to produce a voltage of 2.4V at Vin 101.1 with respect to Vcommon 109. Then if a second pack 105.2 is composed of 12 cells 104.1-104.12, each cell 104 nominally developing 4V, then the pack 105.2 may develop a potential difference of 48V and the developed voltage V2′ 106.2 with respect to Vcommon 109 may equal 96V. Then a resistive divider 108.1, including R1=1R and R2=29R, may divide down the total voltage produced by both packs (105.1 and 105.2) to be measured by the monitoring unit 110.1 in accordance with Equation 1, the developed signal is divided by 30 to produce a voltage of 3.2V at Vin 102.1 with respect to Vcommon 109. Then using Vin 102.1 and Vin 101.1, the developed voltage of the second pack may be calculated. Using the monitoring unit 110.1, including accurate VREF 120.1, the measurement and conversion of the developed voltage from the second pack 105.2, with respect to Vcommon 109, may be assumed to be accurate.

The voltage developed across the second pack 105.2 may additionally be measured by a monitoring unit 110.2. The monitoring unit 110.2 may have a reference voltage VREF 120.2 that is not as accurate as VREF 120.1. Similar to the measurement of the voltage produced across the first pack 105.1, monitoring unit 110.2 may be configured to receive a voltage input from a voltage divider 107.2 representing a fraction of the voltage V2′ 106.2-V1′ 106.1 developed across the pack 105.2. Then the monitoring unit 110.2 may convert the divided measurement signal Vin 101.2 into a digital representation using the internal reference voltage VREF 120.2.

The monitoring unit 110.2 may then be calibrated by comparing the measurement measured at monitoring unit 110.2 and the measurement calculated at monitoring unit 110.1. From the comparison of the two measurements, a correction factor may be determined. The correction factor may be a gain error or multiplying factor that may be used to correct the future measurements taken by the monitoring unit 110.2. Then, once an accurate measurement is determined at monitoring unit 110.2, a similar process may be repeated for the next pack in the stack, calibrating a third monitoring unit with an accurate measurement determined at monitoring unit 110.2. This calibration may be repeated up the stack.

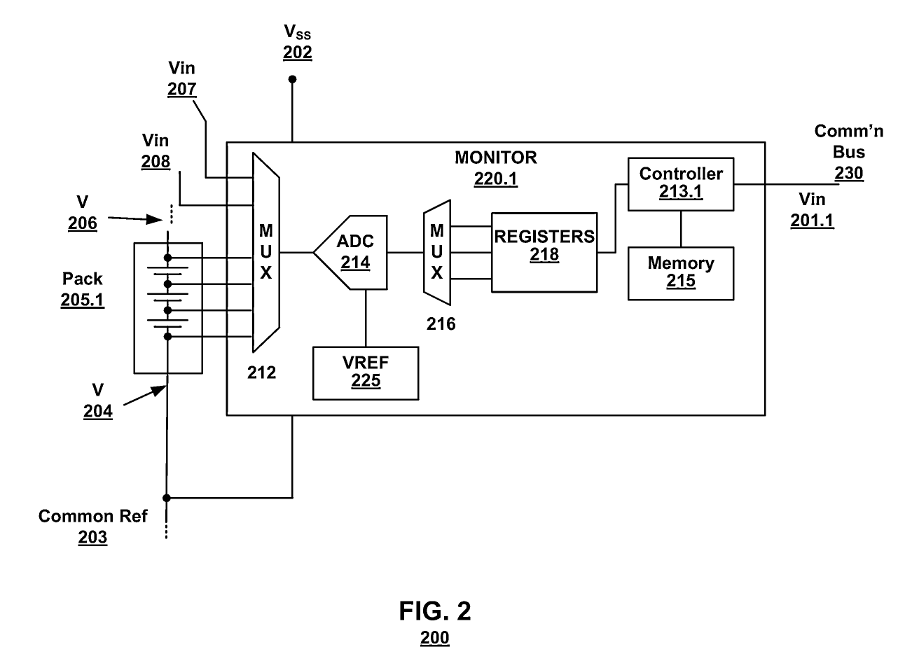

FIG. 2 is a simplified block diagram of an exemplary monitoring unit 200 according to an embodiment of the present invention. Each monitor 220 may be provided as a stand alone integrated circuit chip. The monitor 220.1 may be coupled to a voltage source 205.1 comprising multiple cells arranged in series to develop a total potential voltage V 206-V 204. The monitoring unit may include a first multiplexer (“MUX”) 212 having inputs coupled to the cells of the pack 205.1, an analog-to-digital converter (“ADC”) 214 coupled to an output of the MUX 212; a second MUX 216 coupled to an output of the ADC 214; a register file 218 for storage of digital data output by the ADC 214, a controller 213.1, and a memory 215. The monitor 220.1 may additionally have a power supply Vₛₛ 202 and a common reference 203. The ADC 214 may convert the multiplexed analog measurement signals into digital representations using a reference voltage 225.

The controller 213.1 may include control logic, data registers, and other modules to control monitor 220.1 operations. The monitor 220 may measure the local pack voltage 208 measured as the total pack voltage for the local pack 205.1. The monitor 220.1 may additionally measure the combined pack voltage 207 measured as the total voltage for the combined local pack 205.1 and an adjacent pack 205.2. Then the controller 213.1 may use the combined pack voltage 207 and the local pack voltage 208 to calculate the pack voltage for the adjacent pack 205.2. The controller may additionally receive from the adjacent monitor 205.2 the measured local pack voltage 201 for the adjacent pack 205.2. Using the received value 201, and the calculated pack voltage for the adjacent pack, the controller may calculate a correction factor to adjust subsequent measurements at the adjacent monitor 220.2 Any of the calculated or measured values, including the received value 201 and the calculated correction factor may be stored in memory 213 and/or transmitted to another monitoring unit or processor via a digital communication bus 230.

In an embodiment, the monitor 220.1 may transmit the calculated pack voltage for the adjacent pack 205.2 to the adjacent monitor 220.2. Then the controller 213.2 at the adjacent monitor 220.2 may receive as input the calculated pack voltage for the connected pack 205.2. Using the received value, and the calculated pack voltage for the connected pack 205.2, the controller 213.2 may calculate a correction factor for the adjacent monitor 220.2

As shown in FIG. 2, according to an embodiment, the correction factor may be determined by the internal controller 215 and stored in memory 213. According to an alternate embodiment, the correction factor for each monitoring unit may be developed and stored by an external stack controller, implemented separately from the monitoring units.

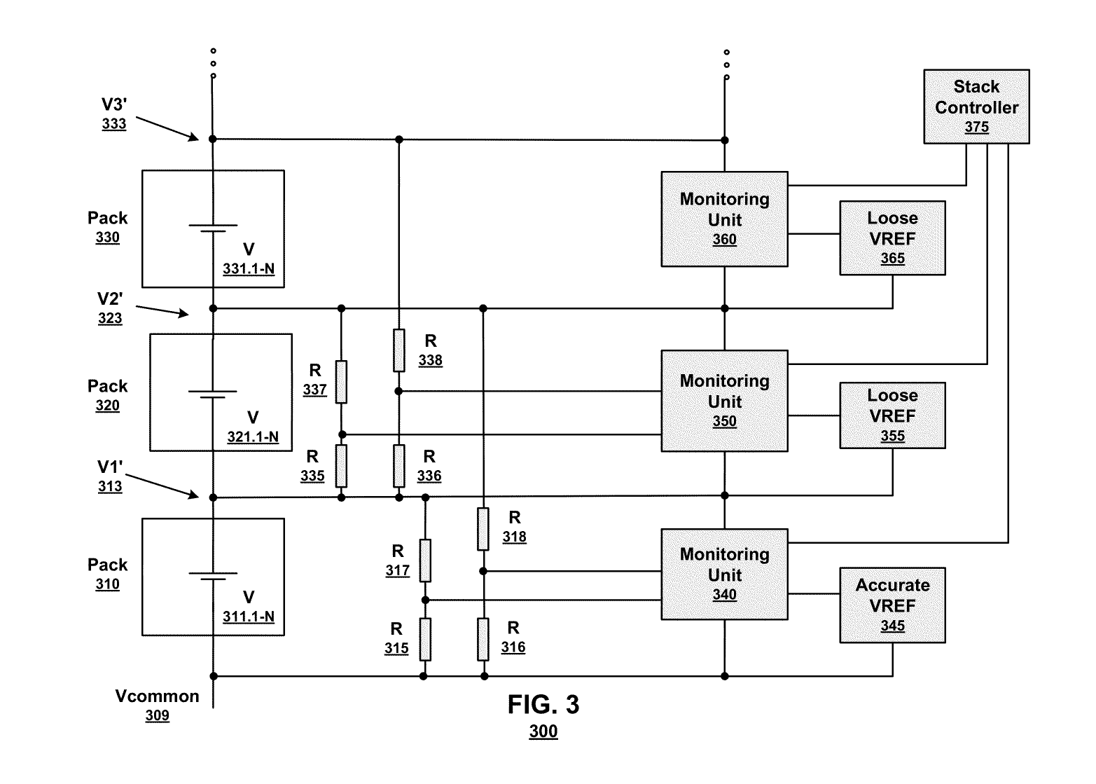

FIG. 3 is a simplified block diagram of an exemplary voltage stack 300 arranged according to an embodiment of the present invention. As shown in FIG. 3, the high voltage stack may include multiple voltage packs 310, 320, 330. Each pack 310, 320, 330 may include one or more voltage cells 311.1-N, 321.1-N, 331.1-N having a small potential difference of a few volts developed across it. Then the total potential difference developed across each pack 310, 320, 330 may be measured by a corresponding monitoring unit 340, 350, 360. Each monitoring unit 340, 350, 360 may include a voltage reference 345, 355, 365 where some voltage references are more accurate than other voltage references. Then a monitoring unit 340 with a voltage reference 345 of known accuracy may be used to calibrate the other monitoring units 350, 360.

For example, if pack 310 may develop a potential difference V1′ 313-Vcommon 309 of 48V, a voltage divider may divide the developed voltage and deliver an input signal to the monitoring unit 340. Then using the voltage reference 345, the monitoring unit 340 may measure V1′ 313-Vcommon 109. Additionally, if the series combination of pack 310 and pack 320 may develop a potential difference V2′ 323-Vcommon 109 of 96V, a voltage divider may divide the developed voltage and deliver an input signal to the monitoring unit 340. Then using the voltage reference 345, the monitoring unit 340 may measure V2′ 323-Vcommon 309. Subsequently the pack voltage across pack 320, V2′ 323-V1′ 313, may be calculated.

After the initial measurements are made, additional measurements may be made and the corresponding monitoring units calibrated. For example, a voltage divider including may divide the developed voltage V2′ 323-V1′ 313 of pack 320, and deliver an input signal to the monitoring unit 350. Then using voltage reference 355, the monitoring unit 350 may measure V2′ 323-V1′313. The two representations of V2′ 323-V1′ 313, one calculated by monitoring unit 340 and one measured by monitoring unit 350, may be compared and a correction factor needed to correct the measurement taken by monitoring unit 350 determined and applied to future calculations at monitoring unit 350.

For example, if monitoring unit 340 calculated a value for pack 320 equivalent to an input signal of 1.000V and monitoring unit 350 measured a value for pack 320 equivalent to an input signal of 1.02V then it may be determined that measurements from monitoring unit 350 are approximately 2% higher than monitoring unit 340. Thus a correction factor of (1/1.02) or 0.9804 is determined for monitoring unit 350. Subsequent measurements from monitoring unit 350 may then be multiplied by the correction factor with the result that the manipulated results calculated from monitoring unit 350 will be as accurate as the measurements from monitoring unit 340.

Then, using the correction factor, the monitoring unit 350 may calculate the potential difference developed across pack 330. A voltage divider may divide the combined developed voltage of pack 320 and pack 330, being V3′ 333-V1′ 313, and deliver an input signal to the monitoring unit 350. Then using voltage reference 355 and the correction factor, the monitoring unit 350 may calculate V3′ 333-V2′ 323. Monitoring unit 360 may additionally measure V3′ 333-V2′ 323 using voltage reference 365. Then the two calculations of V3′ 333-V2′ 323 may be compared and a correction factor needed to correct the measurement taken by monitoring unit 360 may be determined and applied to future calculations at monitoring unit 360.

According to an embodiment, the stack may include a controller 375 configured to control and monitor the monitoring units, to calculate and store the correction factors for each monitoring unit, and to determine if a monitoring unit should be recalibrated. Therefore, a monitoring unit having output adjusted based on an earlier calibration, e.g. calibrated monitoring unit 350, may accurately measure the voltage of an adjacent pack and transmit the known accurate measurement to the stack controller 375. Then the un-calibrated monitoring unit associated with the adjacent pack may measure the voltage and transmit the loose measurement to the stack controller 375. The stack controller may then calculate a correction factor for the associated monitoring unit and apply the correction factor to each subsequent measurement output from the associated monitoring unit, thereby effectively calibrating the associated monitoring unit.

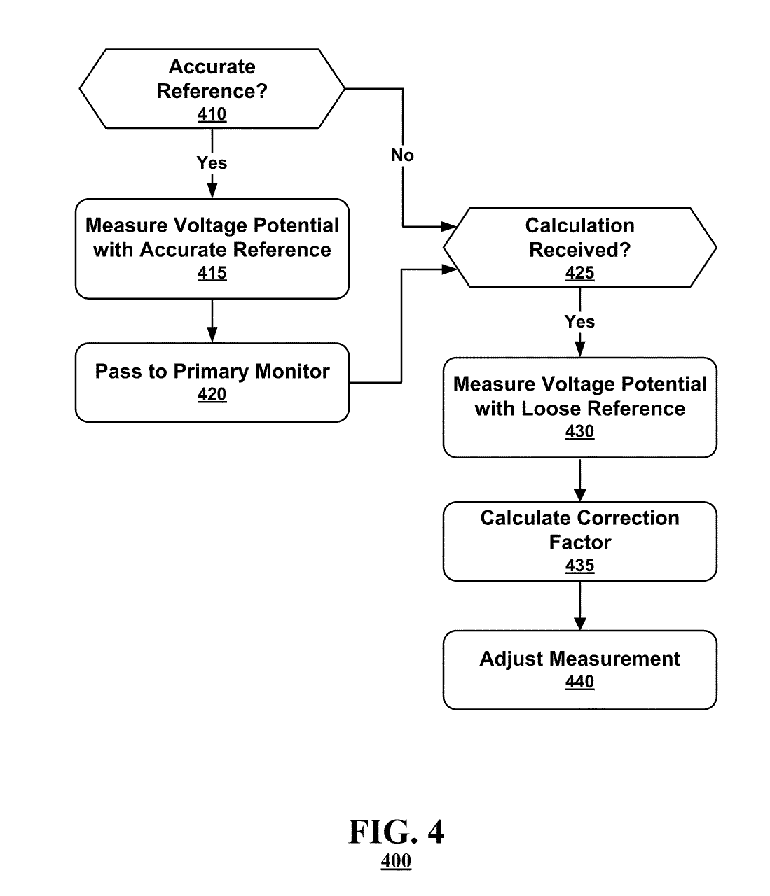

FIG. 4 illustrates an exemplary method 400 for calibrating a monitoring unit according to an embodiment of the present invention. If the monitoring unit has an accurate reference no calibration may be needed (block 410). Then an accurate measurement may be taken for the potential voltage developed across a corresponding voltage module and any additional connected voltage modules (block 415). For any connected or adjacent voltage modules, the calculated accurate measurement may be passed to the corresponding monitoring unit (block 420).

If the current monitoring unit does not have an accurate reference, calibration may be needed to acquire an accurate measurement of the potential developed across a corresponding voltage module. An accurate measurement may be received from another monitoring unit coupled to the current monitoring unit (block 425). The transmitting monitoring unit may be a monitoring unit having an accurate voltage reference or a monitor that was previously calibrated for accurate measurement. The current monitoring unit may then measure the potential developed across a corresponding voltage module (block 430). Then using the received accurate measurement and the calculated measurement, a correction factor for the current monitoring unit may be determined (block 435). Future measurements at the current monitoring unit may then be adjusted by the correction factor to achieve an accurate measurement with the inaccurate monitoring unit (block 440).

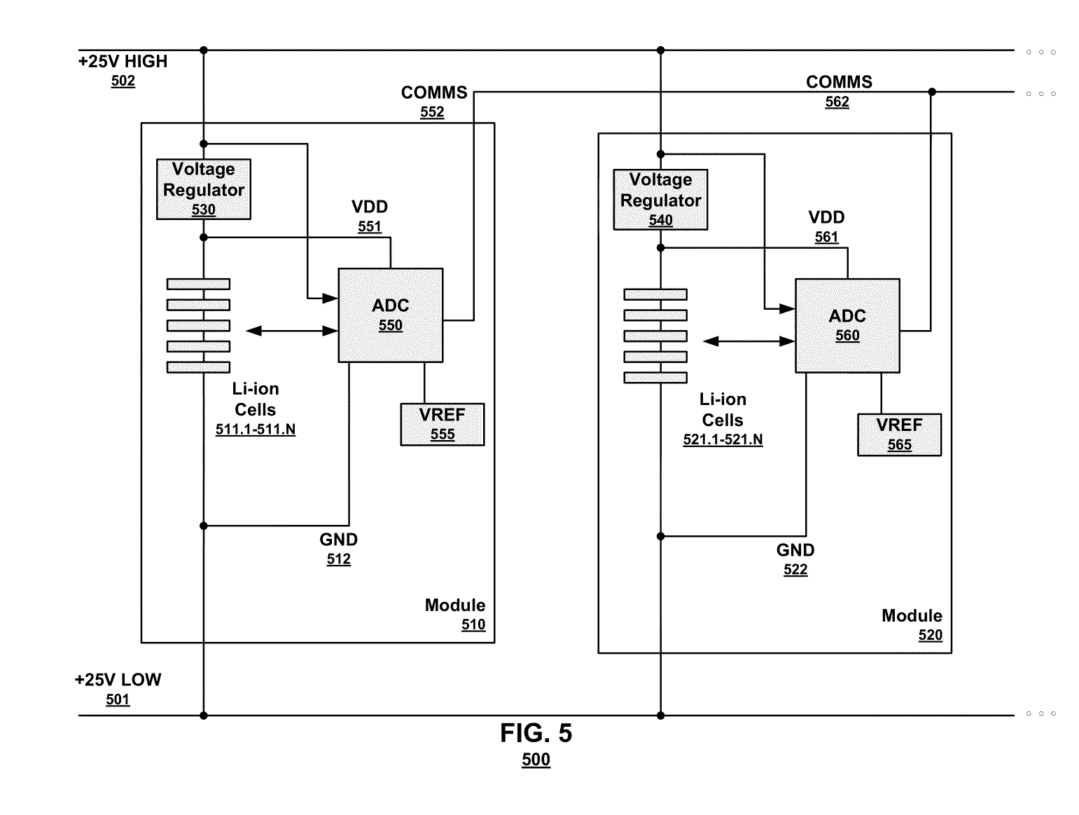

FIG. 5 is a simplified block diagram of an exemplary group of voltage modules 500 arranged according to an embodiment of the present invention. Each voltage module 510, 520 shown in FIG. 5 arranged in parallel, has the same output voltage and may be implemented to produce a regulated output from an unregulated input voltage produced by the Li-ion string of 6 cells. For example, an analog input signal that is common or shared between module 510 and module 520 is the output regulated voltage, shown at 24V 501, 502. Each module 510, 520 includes a number of Li-ion cells 511, 521 in series together with a voltage regulator 530, 540, an ADC 550, 560 and a voltage reference 555, 565.

As shown in FIG. 5, module 510 may include a voltage reference VREF 555, which has a very tight tolerance and module 520 may include a voltage reference VREF 565 which is not as tight as VREF 555. Module 510 might be considered a master module and module 520 and any other module relying on the accurate measurement of module 510 may be considered a support module.

A controller configured to ensure correct operation of the modules may be implemented as part of the module 510, 520, or may be external to and coupled to each module 510, 520. Module 510 and module 520 may simultaneously sample the common analog input signal and report the results, for example to the controller. Then a correction factor for module 520 may be determined and subsequent readings from module 520 treated with this correction factor. The correction factor may be stored with the corresponding module or otherwise may be stored by the controller.

With more modules in the system, additional master modules may be implemented. A secondary master module may then be considered a backup module. If a master module malfunctions, it may be automatically removed from operation, and a backup module may be used for module calibration. According to an embodiment, support modules may then be calibrated against each master module and the correction factors determined with each master module.

Various embodiments may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

Although the present application is described primarily with reference to a voltage monitoring unit, it would be understood by an ordinarily skilled artisan that this application may have applicability to other conversion systems needing accurate results with limited access to accurate references or parameters. For example, if two conversion systems can access the same parameter, whether it be a voltage signal or a current signal or a component value like a resistance value, then the same philosophy as above can apply and an overall high accuracy measurement system can be established even though not every critical component is itself high accuracy.

The foregoing discussion identifies functional blocks that may be used in signal processing systems constructed according to various embodiments of the present invention. In some applications, the functional blocks described hereinabove may be provided as elements of an integrated software system, in which the blocks may be provided as separate elements of a computer program. In other applications, the functional blocks may be provided as discrete circuit components of a processing system, such as functional units within a digital signal processor or application-specific integrated circuit. Still other applications of the present invention may be embodied as a hybrid system of dedicated hardware and software components.

Moreover, the functional blocks described herein need not be provided as separate units. Such implementation details are immaterial to the operation of the present invention unless otherwise noted above. Further, it is noted that the arrangement of the blocks in FIG. 4 does not necessarily imply a particular order or sequence of events, nor is it intended to exclude other possibilities. For example, the operations represent by blocks 415 and 430 may be executed substantially simultaneously.

While the invention has been described in detail above with reference to some embodiments, variations within the scope and spirit of the invention will be apparent to those of ordinary skill in the art. Thus, the invention should be considered as limited only by the scope of the appended claims.

What is claimed is:

1. A monitoring system comprising a plurality of monitors, each monitor having an input pair coupled to respective components;
wherein a first monitor is coupled to a first component and a second component and a second monitor is coupled to the second component;
wherein the first monitor is configured to measure an input from the first component and an input from the second component the second monitor is configured to measure an input from the second component; and
wherein a correction factor for the second monitor is determined from the measurements input from the first and second components.

2. The system of claim 1, further comprising a pair of reference voltage sources, each connected to a respective monitor, wherein the reference source connected to the first monitor is a higher precision voltage source than the reference source connected to the second monitor.

3. The monitoring system of claim 1, wherein the components are battery stacks.

4. The monitoring system of claim 1, wherein the second monitor adjusts subsequent measurements of the component based on the correction factor.

5. The monitoring system of claim 1, further comprising a resistive divider arranged to divide a voltage across the component to a voltage domain of the first monitor.

6. The monitoring system of claim 1, further comprising a controller configured to control the operation of a monitor.

7. The monitoring system of claim 1, wherein the correction factor for a monitor is calculated by the controller.

8. The monitoring system of claim 1, wherein the measurement from the second component received at the first monitor includes a combined measurement for both the first component and the second component.

9. The monitoring system of claim 8, wherein the first monitor calculates a measurement for the second component from the combined measurement.

10. The monitoring system of claim 9, wherein the first monitor receives a measurement of the second component from the second monitor and determines the correction factor.

11. The monitoring system of claim 9, wherein the second monitor receives the calculated measurement of the second component from the first monitor and determines the correction factor.

12. The monitoring system of claim 8, wherein the second monitor receives the combined measurement from the first monitor.

13. The monitoring system of claim 12, wherein the second monitor calculates a measurement for the second component and determines the correction factor.

14. An integrated circuit, comprising:
a converter to locally measure input voltage from a local voltage source;
a converter to locally measure input voltage combining the local voltage source and an adjacent voltage source;
a receiver to receive data representing a measurement of the adjacent voltage source; and
a controller to calculate a correction factor based on the local voltage source measurement, the combined voltage source measurement, and the received measurement.

15. The circuit of claim 14, further comprising:
a transmitter operable to transmit a measurement to another integrated circuit.

16. The circuit of claim 14, further comprising an internal reference voltage circuit.

17. The circuit of claim 14, further comprising a reference voltage source coupled to the integrated circuit.

18. The circuit of claim 14, further comprising:
a plurality of inputs, one coupled to the voltage source, one coupled to the adjacent voltage source, and others coupled to components of the voltage source, and
a multiplexer selectively coupling the inputs to the converter,
wherein the subsequent measurements occur when the multiplexer connects other inputs to the converter.

19. The circuit of claim 14, wherein the voltage source is a stack of battery cells and the voltage source is connected to the integrated circuit by a voltage divider.

20. An integrated circuit, comprising:
a converter to locally measure input voltage from a local voltage source;
a converter to locally measure input voltage combining the local voltage source and an adjacent voltage source;
a controller to calculate the voltage for the adjacent voltage source with the local voltage source measurement and the combined voltage source measurement; and
a transmitter to transmit the calculated voltage to an adjacent integrated circuit for use in calculating a correction factor for the adjacent voltage source.

21. The circuit of claim 20, further comprising an internal reference voltage circuit.

22. The circuit of claim 20, further comprising a reference voltage source coupled to the integrated circuit.

23. A calibration method for an integrated circuit, comprising:
locally measuring an input voltage from a local voltage source of the integrated circuit;
locally measuring an input voltage that combines the local voltage source with an adjacent voltage source to the integrated circuit;
calculating a measurement of the adjacent voltage source; and
generating a correction factor from the measured local voltage source and the calculated adjacent voltage source.

24. The method of claim 23, further comprising:
transmitting the correction factor to a system controller.

25. The method of claim 23, wherein the correction factor is generated at a system controller.

26. A calibration method for an integrated circuit, comprising:
locally measuring an input voltage from a local voltage source of the integrated circuit;
receiving a measurement of the local voltage source;
generating a correction factor from the measured local voltage source and the received measurement of the local voltage source; and
adjusting subsequent local measurements by the correction factor.

27. The method of claim 26, further comprising:
locally measuring an input voltage that combines the local voltage source with an adjacent voltage source to the integrated circuit;
adjusting the local measurement of the local voltage source by the correction factor;
calculating a measurement of the adjacent voltage source; and
generating a correction factor from the measured local voltage source and the calculated adjacent voltage source.

28. The method of claim 26, wherein the received data is received from an adjacent integrated circuit.

29. The method of claim 26, wherein the received data is received from a system controller.

30. The method of claim 26, wherein the correction factor is generated at a system controller.

31. A system controller, comprising:
a receiver to receive measurements of respective components of a component stack, wherein adjacent monitoring devices measure a common component; and
a processor to calculate a correction factor for a second monitoring device based on the measurements calculated at a first monitoring device and to adjust all measurements received from the second monitoring device based on the calculated correction factor.

32. A system comprising:
a plurality of battery stacks, each battery stack comprising a plurality of battery cells;
a plurality of monitors, each monitor having an input pair coupled to respective battery stacks;
a plurality of resistive dividers;
wherein a first monitor is coupled to a first battery stack and a second battery stack and a second monitor is coupled to the second battery stack;
wherein the first monitor is configured to measure an input from the first battery stack and an input from the second battery stack and the second monitor is configured to measure an input from the second battery stack;
wherein each monitor input is divided with a respective one of the plurality of resistive dividers is arranged to divide a voltage across a battery stack to a voltage domain of the respective monitor;
wherein a correction factor for the second monitor is determined from the measurements input from the first and second battery stacks.

33. The system of claim 32, further comprising a plurality of reference voltage sources, each connected to a respective monitor, wherein the reference source connected to the first monitor is a higher precision voltage source than the reference source connected to the second monitor.
